(19) United States
(12) Patent Application Publication
(10) Pub. No.: US 2005/0134342 A1
(43) Pub. Date: Jun. 23, 2005

(54) Circuit and method for generating a signal pulse

(76) Inventors: Yung-Lung Lin, Hsinchu Science (TW); Hung-Jen Liao, Hsinchu Science (TW)

Correspondence Address: DUANE MORRIS, LLP;IP DEPARTMENT, ONE LIBERTY PLACE, PHILADELPHIA, PA, 19103-7396, US

(21) Appl. No.: 10/741,576

(22) Filed: Dec. 18, 2003

(51) Int. Cl. H03K 3/017

(52) U.S. Cl. 327/174

(57) ABSTRACT

A pulse generator is disclosed which comprises a clock buffer coupled to a data latch coupled to a delay unit; a logic device coupled to the delay unit and the data latch, the logic device adapted to logically combine signals generated from the delay unit and the data latch and to generate a signal pulse; and a signal reset unit coupled to the data latch. A method of generating a pulse is also disclosed, comprising generating a signal state by sensing a rising edge of an external clock; latching the signal state for generating a latched signal state; delaying the latched signal state for generating a delayed signal state; and logically combining the latched signal state and the delayed signal state for generating a signal pulse.

### FIELD OF THE INVENTION

The present invention relates to a circuit and a method for generating and/or controlling signal pulses in a semiconductor integrated circuit.

### DESCRIPTION OF THE RELATED ART

Clock signals have been widely used in a variety of semiconductor integrated circuits to control the timing of various events occurring during the operation of the circuits. For example, in synchronous static random access memory (SRAM), pulses for word-line activation, sense-amplifier firing, and/or equalization are typically generated by external clock signals. In order to provide signal pulses, an external clock serves as a signal source thereof. For certain circuits, the signal pulse width should be wider than a pre-determined signal pulse width or those circuits could malfunction.

FIG. 1 illustrates a traditional pulse generator. The pulse generator comprises first inverter 100, delay unit 110, NAND gate 120, and second inverter 130. An external clock is applied to the input terminal 105 of the first inverter 100. The first inverter 100 and the delay unit 110 can then invert and delay, respectively, the external clock and generate a delayed signal at the first input terminal 115 of the NAND gate 120. In addition, the external clock is applied to the second terminal 125 of the NAND gate 120. The NAND gate 120 NANDs the delayed signal at the first input terminal 115 of the NAND gate 120 and the external clock at the second terminal 125 of the NAND gate 120, and generates a NANDed signal to the second inverter 130. The second inverter 130 inverts the NANDed signal and generates a final signal at the output terminal 135 of the inverter 130. However, the width of the final signal generated from the second inverter 130 is narrower than that of the external clock. Therefore, in order to generate a signal pulse with a sufficiently larger width, a wider external clock is required to serve for the pulse generator of FIG. 1, increasing the operational time of generating the signal pulse.

FIG. 2 illustrates another traditional pulse generator. The traditional pulse generator comprises first, second, and third delay units 200, 210, and 220 respectively, a NOR gate 230 and an inverter 240. An external clock is applied at the input terminal 205 of the pulse generator and coupled to the first input terminal 215 of the NOR gate 230. The first delay unit 200 delays the external clock and generates a first delayed signal at the second input terminal 225 of the NOR gate 230. The second and third delay units 210 and 220, respectively, delay the external clock and generate a second delayed signal at the third input terminal 235 of the NOR gate 230. The NOR gate then NORs the external clock, the first delayed signal, and the second delayed signal and generates a NORed signal to the inverter 240. Finally the inverter 240 inverts the NORed signal and generates a final signal at the output terminal 245 of the pulse generator. Although such a traditional pulse generator creates the final signal having a width wider than that of the external clock, the design of the delay chain circuits would be complicated and would further increase the size of the pulse generator.

### BRIEF DESCRIPTION OF THE DRAWINGS

FIG. 1 is a schematic representation of a prior art pulse generator.

FIG. 2 is a schematic representation of another prior art pulse generator.

FIG. 3 is a schematic block diagram representation illustrating an exemplary pulse generator in accordance with the present invention.

FIG. 4A is a schematic representation illustrating an exemplary clock buffer in accordance with the present invention.

FIG. 4B is a schematic representation illustrating an exemplary signal generator in accordance with the present invention.

FIG. 4C is a schematic representation illustrating an exemplary signal reset unit in accordance with the present invention.

FIG. 5 is a schematic representation illustrating of an exemplary pulse generator in accordance with the present invention.

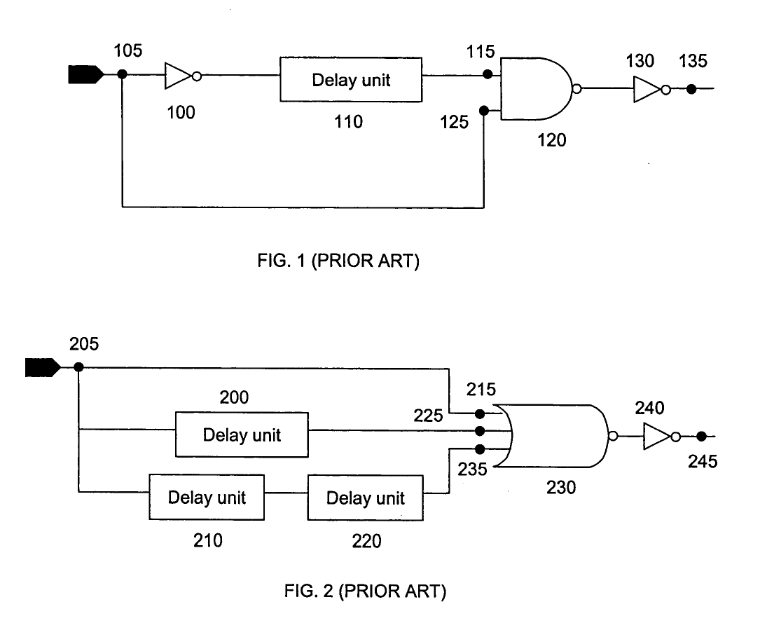

### DESCRIPTION OF EXEMPLARY EMBODIMENTS

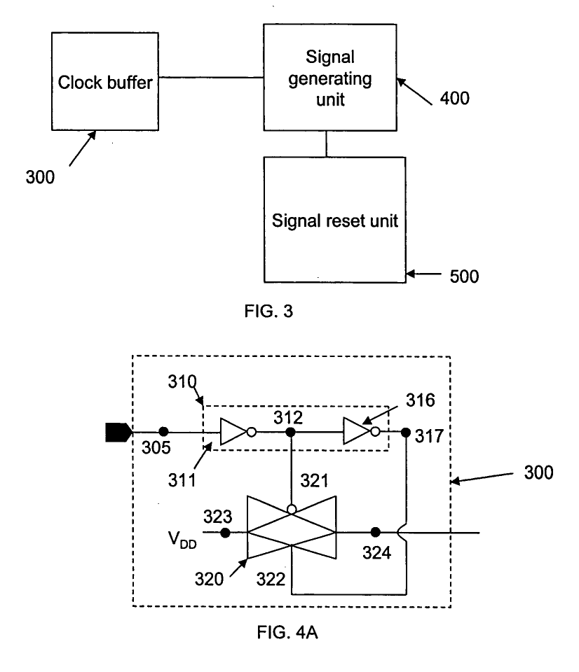

Referring now to FIG. 3, a schematic block diagram of an exemplary pulse generator for generating a pulse having a width wider than that of an external clock, the pulse generator comprises clock buffer 300, signal generator 400, and signal reset unit 500. In certain embodiments, clock buffer 300, signal generator 400, and signal reset unit 500 may be coupled to each other.

Clock buffer 300 is coupled to signal generator 400. In a preferred embodiment, clock buffer 300 is adapted to generate a signal state in response to a rising edge of an external clock.

Signal generator 400 is, coupled to the signal reset unit 500. Signal generator 400 is adapted to latch the signal state obtained from clock buffer 300, delay the signal state, and generate a signal pulse.

Signal reset unit 500 is adapted to reset the signal state latched by the signal generator 400.

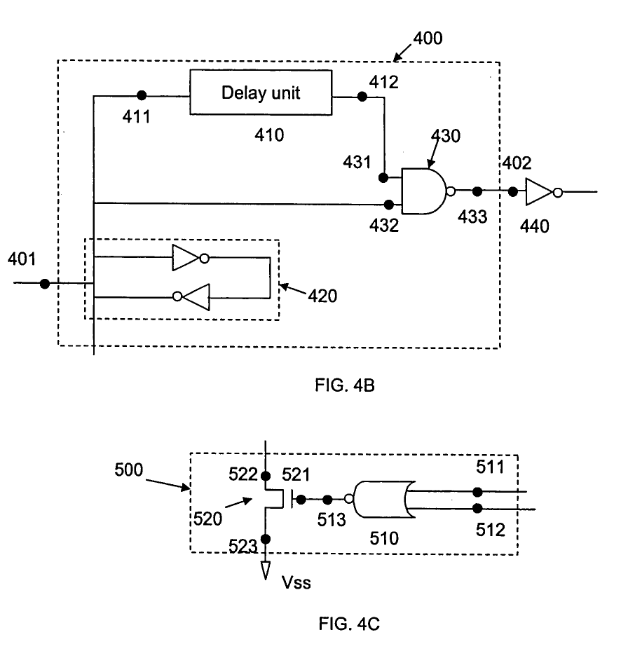

As illustrated in FIG. 4A, a schematic configuration of an exemplary clock buffer, clock buffer 300 comprises inverter unit 310 and transmission gate 320 coupled to inverter unit 310. In the embodiment illustrated in FIG. 4A, inverter unit 310 comprises first inverter 311 and second inverter 316 coupled to each other in series. In a preferred embodiment, transmission gate 320 is adapted to generate a signal state, e.g. a high or low state, in response to the rising edge of the external signal and may be controlled by signals generated from inverter unit 310. Transmission gate 320 may comprise, for example, a P-type MOS (PMOS), an N-type MOS (NMOS), a complementary MOS (CMOS) transistor, or the like, or a combination thereof.

Gate terminals of transmission gate 320 may be adapted to receive signals generated from first inverter 311 and second inverter 316. In the embodiment illustrated in FIG. 4A, output terminal 312 of first inverter 311 is further coupled to gate terminal 321, e.g. a PMOS transistor of transmission gate 320, and output terminal 317 of second inverter 316 is coupled to the gate terminal 322, e.g. an NMOS transistor of transmission gate 320.

In the embodiment illustrated in FIG. 4A, input terminal 323 of transmission gate 320 is coupled to a supply power voltage, e.g. V_{DD}. In some embodiments, transmission gate 320 comprises a PMOS transistor and second inverter 316 may not be required because output terminal 312 of first inverter 311 can control the signal coming from input terminal 323 of transmission gate 320. The type of transmission gate 320 and the number of inverter units 310 may be configured depending on the performance and size of clock buffer 300.

As illustrated in FIG. 4A, transmission gate 320 can generate a signal state, such as high state in the exemplary embodiment illustrated in FIG. 4A. For example, when an external clock signal having a rising edge is applied to input terminal 305 of first inverter 311, the output signals generated from output terminal 312 of first inverter 311 and output terminal 317 of second inverter 316 are coupled to gate terminals 321 and 322 of transmission gate 320. These output signals may then turn on transmission gate 320 which allows passing the V_{DD} signal at input terminal 323 of transmission gate 320 to output terminal 324 of transmission gate 320.

As illustrated in FIG. 4B, a schematic configuration showing an exemplary signal generator, signal generator 400 comprises input terminal 401 coupled to clock buffer 300 (FIG. 3), output terminal 402 operatively coupled to signal reset unit 500 (FIG. 3), delay unit 410, data latch 420, and first logic device 430.

Data latch 420 is coupled to clock buffer 300 (FIG. 4A). Data latch 420 is adapted to latch the signal state generated from clock buffer 300 (FIG. 3) and to generate a latched signal state. The data latch 420 can be, for example, cross-coupled inverters, NOR D-Latch, or the like, or a combination thereof.

Delay unit 410 is coupled to data latch 420, e.g. at input terminal 411. Delay unit 410 comprises input terminal 411 coupled to data latch 420 and output terminal 412 coupled to first input terminal 43 1 of first logic device 430. Delay unit 410 is adapted to delay the latched signal state and to generate a delayed signal state. Delay unit 410 can be, for example, a series of inverters or the like.

First logic device 430 comprises output terminal 433 coupled to output terminal 402 of signal generator 400. First logic device 430 is adapted to logically combine signals representing the latched signal state and the delayed signal state and to generate a signal pulse. First logic device 430 can be, for example, a NOR gate, a NAND gate, an OR gate, an AND gate, or the like, or a combination thereof. Actual configuration of data latch 420, delay unit 410, and first logic device 430 may be a function of the desired performance and size of signal generator 400.

In the embodiment illustrated in FIG. 4B, data latch 420 latches the signal state, such as high state, generated form clock buffer 300 (FIG. 3) and generates a latched signal state in response to the signal state generated from clock buffer 300 (FIG. 3). The latched signal state is then coupled to input terminal 411 of delay unit 410 and second input terminal 432 of first logic device 430. Delay unit 410 delays the latched signal state and generates a delayed signal state at output terminal 412 of the delay unit 410. The delayed signal state is then coupled to first input terminal 431 of first logic device 430. In the embodiment illustrated in FIG. 4B, first logic device 430 is a NAND gate which NANDs the latched signal state and the delayed signal state from the input terminals 432 and 431, respectively, and generates a signal pulse at the output terminal 433. The output signal pulse is then coupled to output terminal 402. In addition, delay unit 410 is adapted to control the width of the signal pulse generated from first logic device 430. From the design of delay unit 410, the width of the signal pulse generated from first logic device 430 can be wider than that of the external clock input from input terminal 305 (FIG. 4A) of first inverter 311 (FIG. 4A).

In some embodiments, signal generator 400 may further comprise inverter 440 coupled to output terminal 433. Inverter 440 is adapted to invert the signal pulse generated from output terminal 433. Inclusion of inverter 440 may depend on the shape of the signal pulse. For example, if the state of the signal pulse generated form the output terminal 433 of first logic device 430 is suitable for the operation of circuits (not illustrated), inverter 440 is not required.

FIG. 4C illustrates a schematic configuration of an exemplary signal reset unit 500. In the embodiment illustrated in FIG. 4C, signal reset unit 500 comprises second logic device 510 and switch 520 coupled to second logic device 510. Switch 520 comprises first terminal 522 coupled to signal generator 400 (FIG. 3), and second terminal 523 coupled to a Vₛₛ terminal, such as ground. Second logic device 510 comprises output terminal 513 coupled to switch 520 and first and second input terminals 511 and 512, respectively.

Switch 520 is adapted to couple the latched signal state generated from data latch 420 (FIG. 4B) to the Vₛₛ terminal. Switch 520 can be, for example, a diode, a transistor, an NMOS transistor, a PMOS transistor, a CMOS transistor, or the like, or a combination thereof. Second logic device 510 is adapted to receive signals generated from output terminal 433 (FIG. 4B) of first logic device 440 (FIG. 4B) and output terminal 317 (FIG. 4A) of inverter unit 310 (FIG. 4A), then logically combine the output signals generated therefrom.

Second logic device 510 generates an output signal at output terminal 513 which may be used to control switch 520, e.g. for coupling the latched signal state generated from data latch 420 (FIG. 4B) to the Vₛₛ terminal. In the embodiment illustrated in FIG. 4C, second logic device 510 is a NOR gate. However, second logic device 510 can be, for example, a NOR gate, a NAND gate, an OR gate, an AND gate, or the like, or a combination thereof.

Selections of switch 520 and second logic device 510 may be decided based in whole or in part on the desired performance and size of signal reset unit 500.

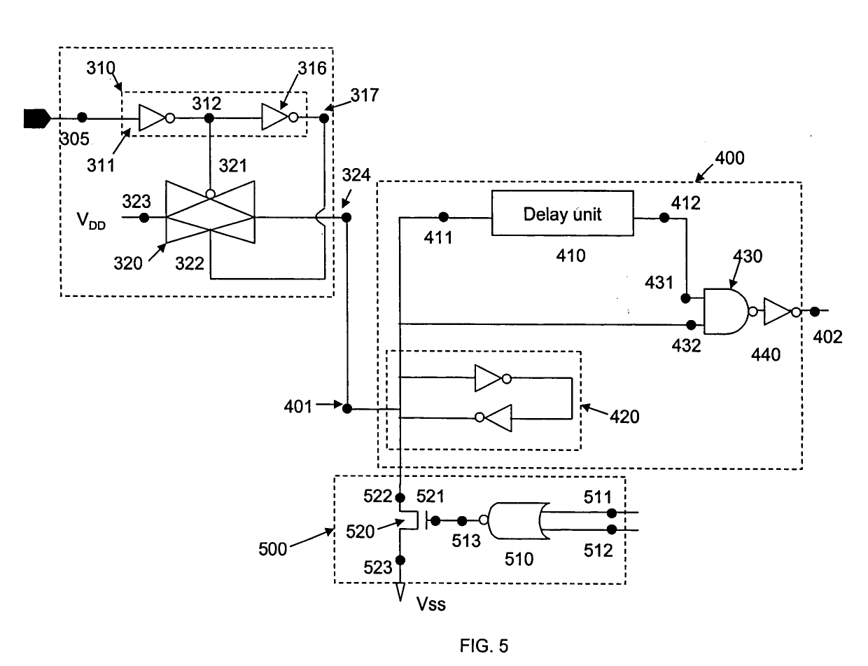

FIG. 5 illustrates a schematic configuration of an exemplary pulse generator which combines clock buffer 300, signal generator 400, and signal reset unit 500.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A pulse generator, comprising:
a. a signal generator, comprising a delay unit, a data latch coupled to the delay unit, coupled to the data latch, and a logic device coupled to the delay unit and the data latch, the logic device adapted to logically combine signals generated from the delay unit and the data latch and to generate a signal pulse;
b. a clock buffer coupled to the data latch; and
c. a signal reset unit coupled to the data latch.

2. The pulse generator of claim 1, wherein the signal generator further comprises an inverter coupled to the logic device.

3. The pulse generator of claim 1, wherein the clock buffer is adapted to generate a signal state in response to at least one of (i) a rising edge of an external clock or (ii) a falling edge of an external clock.

4. The pulse generator of claim 3, wherein a width of the signal pulse generated from the logic device is wider than a width of a signal pulse generated from the external clock.

5. The pulse generator of claim 3, wherein the clock buffer further comprises:
a. a transmission gate; and
b. an inverter unit coupled to the transmission gate.

6. The pulse generator of claim 5, wherein the inverter unit further comprises a first inverter coupled in series to a second inverter.

7. The pulse generator of claim 6, wherein the transmission gate further comprises a complementary MOS (CMOS) transistor.

8. The pulse generator of claim 7, wherein a gate terminal of the CMOS transistor is adapted to receive a signal generated from the inverter unit.

9. The pulse generator of claim 1, wherein the delay unit is adapted to control a width of the signal pulse generated from the logic device.

10. The pulse generator of claim 1, wherein the logic device comprises a NAND gate.

11. The pulse generator of claim 3, wherein the data latch is adapted to latch the signal state and generate a latched signal state.

12. The pulse of generator of claim 11, wherein the signal reset unit is adapted to reset the latched signal state.

13. The pulse generator of claim 5, wherein the signal reset unit comprises a switch coupled to a second logic device, the second logic device adapted to receive signals generated from an output terminal of the logic device and an output terminal of the inverter unit.

14. The pulse generator of claim 13, wherein the switch comprises an MOS transistor.

15. The pulse generator of claim 13, wherein the second logic device comprises a NOR gate.

16. A pulse generator, comprising:
a. a clock buffer adapted to generate a signal state in response to a rising edge of an external clock;
b. a signal generator coupled to the clock buffer, the signal generator adapted to latch the signal state, delay the signal state, and generate a signal pulse; and
c. a signal reset unit coupled to the signal generator, the signal reset unit adapted to reset the signal state latched by the signal generator.

17. The pulse generator of claim 16, wherein a width of the signal pulse generated from the signal generator is wider than a width of a signal pulse generated from the external clock.

18. The pulse generator of claim 16, wherein the clock buffer comprises:
a. a transmission gate; and
b. an inverter unit coupled to the transmission gate.

19. The pulse generator of claim 18, wherein the inverter unit comprises at least one of (i) an inverter or (ii) a first inverter coupled in series to a second inverter.

20. The pulse generator of claim 19, wherein the transmission gate further comprises a complementary MOS (CMOS) transistor.

21. The pulse generator of claim 20, wherein a gate terminal of the CMOS transistor is adapted to receive a signal generated from at least one of (i) the first inverter or (ii) the second inverter.

22. The pulse generator of claim 16, wherein the signal generator comprises
a. a data latch coupled to the clock buffer;
b. a delay unit coupled to the data latch; and
c. a logic device coupled to the delay unit and the data latch, the logic device adapted to logically combine signals generated from the delay unit and the data latch.

23. The pulse generator of claim 22, further comprising an inverter coupled to the logic device.

24. The pulse generator of claim 22, wherein the delay unit is adapted to control a width generated from the signal generator.

25. The pulse generator of claim 22, wherein the logic device comprises a NAND gate.

26. The pulse generator of claim 16, wherein the signal reset unit further comprises:
a. a second logic device; and
b. a switch coupled to the second logic device.

27. The pulse generator of claim 26, wherein the switch comprises a MOS transistor.

28. The pulse generator of claim 26, wherein the second logic device comprises a NOR gate.

29. The pulse generator of claim 26, wherein input terminals of the second logic device are adapted logically combine signals generated from an output terminal of the signal generator and an output terminal of the inverter unit.

30. A method of generating a pulse, comprising:
a. generating a signal state by sensing a rising edge of an external clock;
b. latching the signal state;
c. using the latched signal state to generate a second latched signal state;
d. delaying the second latched signal state for generating a delayed signal state; and
e. logically combining the second latched signal state and the delayed signal state for generating a signal pulse.

31. The method of claim 30, wherein a width of the signal pulse is wider than that of a pulse obtained from the external clock.

32. The method of claim 30, wherein generating a signal state by sensing a rising edge of an external clock further comprises:
a. coupling the external clock to an inverter; and
b. coupling an output signal of the inverter to a transmission gate.

33. The method of claim 32, further comprising:
a. coupling the output signal of the inverter to second inverter; and
b. coupling an output signal of the second inverter to the transmission gate.

34. The method of claim 30, wherein using the latched signal state to generate a second latched signal state further comprises controlling a width of the signal pulse generated by delaying the second latched signal state for generating a delayed signal state.

35. The method of claim 30, wherein delaying the second latched signal state for generating a delayed signal state further comprises NANDing the latched signal state and the delayed signal state.

36. The method of claim 30, further comprising inverting the signal pulse.

37. The method of claim 33, further comprising resetting the latched signal state.

38. The method of claim 37, wherein resetting the latched signal state further comprises:
a. logically combining the output signal of the second inverter and the signal pulse generated from delaying the second latched signal state for generating a delayed signal state; and
b. coupling an output signal generated therefrom to a switch for resetting the latched signal state.

39. The method of claim 38, wherein logically combining the output signal of the inverter and the signal pulse further comprises NORing the output signal of the second inverter and the signal pulse generated from delaying the second latched signal state for generating a delayed signal state.
